(19) United States
(12) Patent Application Publication
(10) Pub. No.: US 2011/0284372 A1
(43) Pub. Date: Nov. 24, 2011

(54) Cu-Ga ALLOY MATERIAL, SPUTTERING TARGET, METHOD OF MAKING Cu-Ga ALLOY MATERIAL, Cu-In-Ga-Se ALLOY FILM, AND METHOD OF MAKING Cu-In-Ga-Se ALLOY FILM

(75) Inventors: Yuichi HIRAMOTO, Tsuchiura (JP); Tatsuya TONOGI, Tsuchiura (JP); Noriyuki TATSUMI, Kasumigaura (JP)

(73) Assignee: HITACHI CABLE, LTD., Tokyo (JP)

(21) Appl. No.: 13/101,461

(22) Filed: May 5, 2011

(30) Foreign Application Priority Data
May 19, 2010 (JP) 2010-115198

(51) Int. Cl. C23C 14/34; B22F 3/10; B22F 3/12; B22F 3/24; C22C 28/00; C22C 30/02

(52) U.S. Cl. 204/298.13; 420/555; 420/587; 419/1; 419/29

(57) ABSTRACT

According to one embodiment of the invention, a Cu—Ga alloy material has an average composition consisting of not less than 32% and not more than 53% by mass of gallium (Ga) as well as the balance consisting of copper (Cu) and an inevitable impurity. In the Cu—Ga alloy material, a region containing less than 47% by mass of copper accounts for 2% or less by volume of the whole Cu—Ga alloy material.

The present application is based on Japanese patent application No.2010-115198 filed on May 19, 2010, the entire contents of which are incorporated herein by reference.

### BACKGROUND OF THE INVENTION

1. Field of the Invention

The present invention relates to a Cu—Ga alloy material, a sputtering target, a method of making a Cu—Ga alloy material, a Cu—In—Ga—Se alloy film, and a method of making a Cu—In—Ga—Se alloy film, in particular, to a Cu—Ga alloy material usable for solar batteries, a sputtering target usable for solar batteries, a method of making a Cu—Ga alloy material usable for solar batteries, a Cu—In—Ga—Se alloy film usable for solar batteries, and a method of making a Cu—In—Ga—Se alloy film usable for solar batteries.

2. Description of the Related Art

Previously, a Cu—Ga binary alloy sputtering target containing a component and a two-phase coexistence structure is known. Here, the component contains 30% to 60% by mass of Ga and the balance consisting of Cu. The two-phase coexistence structure contains Ga-rich Cu—Ga binary alloy grains and grain boundary phase surrounding that. The Ga-rich Cu—Ga binary alloy grains contain more than 30% by mass of Ga and the balance consisting of Cu. The grain boundary phase is composed of Ga-poor Cu—Ga binary alloy containing less than 15% by mass of Ga. The conventional Cu—Ga binary alloy sputtering target, for example, is disclosed in JP-A-2008-138232.

The Cu—Ga binary alloy sputtering target disclosed in JP-A-2008-138232 is used for forming a light-absorbing layer composed of Cu—In—Ga—Se quaterary alloy film in solar batteries, and can be formed at high yield because of the structure thereof

### SUMMARY OF THE INVENTION

However, the Cu—Ga binary alloy sputtering target disclosed in JP-A-2008-138232 is formed by sintering raw powder. Thus, it is difficult to densify the structure of the sputtering target and trouble such as abnormal electrical discharge may occur during sputtering with the sputtering target. Additionally, upsizing of the sputtering target is difficult because it is required to apply high pressure to the raw powder for the densification. Furthermore, Cu—Ga binary alloy containing 32% or more by mass of Ga is melted and cast, and segregation phase containing 80% or more by mass of Ga thereby occurs in the Cu—Ga binary alloy. Use of the sputtering target containing the segregation phase causes a trouble in which the segregation phase is melted by heat during the sputtering.

Accordingly, an object of the present invention is to provide a Cu—Ga alloy material containing less segregation phase, a sputtering target containing less segregation phase, and a method of making a Cu—Ga alloy material containing less segregation phase.

Additionally, another object of the present invention is to provide a Cu—In—Ga—Se alloy film used for a light-absorbing layer of a solar battery and made by sputtering using the sputtering target as well as a method of making the Cu—In—Ga—Se alloy film.

(1) According to one embodiment of the invention, a Cu—Ga alloy material has:

an average composition consisting of not less than 32% and not more than 53% by mass of gallium (Ga) as well as the balance consisting of copper (Cu) and an inevitable impurity,

wherein a region containing less than 47% by mass of copper accounts for 2% or less by volume of the whole Cu—Ga alloy material.

In the above embodiment (1) of the invention, the following modification and change can be made.

(i) The average composition contains not less than 32% and not more than 45% by mass of gallium; and

a region containing less than 35% by mass of copper accounts for 2% or less by volume of the whole Cu—Ga alloy material.

(2) According to another embodiment of the invention, a Cu—Ga alloy material has: an average composition consisting of not less than 32% and not more than 53% by mass of gallium (Ga) as well as the balance consisting of copper (Cu), an inevitable impurity and inevitable voids,

wherein a region consisting of a Cu—Ga alloy phase and the inevitable voids accounts for 2% or less by volume of the whole Cu—Ga alloy material, the Cu—Ga alloy phase contains 80% or more by mass of gallium.

(3) According to another embodiment of the invention, a Cu—Ga alloy material, has: an average composition consisting of not less than 32% and not more than 45% by mass of gallium (Ga) as well as the balance consisting of copper (Cu), an inevitable impurity and inevitable voids,

wherein a region consisting of a Cu—Ga alloy phase and the inevitable voids accounts for 2% or less by volume of the whole Cu—Ga alloy material, the Cu—Ga alloy phase contains 65% or more by mass of gallium; and

the Cu—Ga alloy phase contains at least one of γ1 phase, γ2 phase, and γ3 phase.

(4) According to another embodiment of the invention, a sputtering target is made from the Cu—Ga alloy material according to the above embodiment (1).

(5) According to another embodiment of the invention, a method of making a Cu—Ga alloy material containing a plurality of Cu—Ga alloy phases comprises:

sintering by pressing and heating Cu—Ga alloy powder containing at least one of the Cu—Ga alloy phases.

In the above embodiment (5) of the invention, the following modification and change can be made.

(i) The Cu—Ga alloy powder has a grain diameter of 150 μm or less.

(ii) A part of Cu—Ga alloy powder has a grain diameter of not less than 1 μm and not more than 100 μm; and

the part accounts for 90% or more by volume of the whole of the whole Cu—Ga alloy material.

(iii) the Cu—Ga alloy material consists of not less than 32% and not more than 53% by mass of gallium (Ga) as well as the balance consisting of copper (Cu) and an inevitable impurity; and

in the sintering, powder consisting of phase of which an average composition contains 53% or more by mass of gallium and powder comprising at least first Cu—Ga alloy phase and second Cu—Ga alloy phase are heated at a temperature in a range of 254° C. to 840° C. to melt the first Cu—Ga alloy phase and a part of the second Cu—Ga alloy phase and are pressed at a pressure of 50 MPa or more, the first Cu—Ga alloy phase having a first melting point, and the second Cu—Ga alloy phase having a second melting point higher than the first melting point.

(6) According to another embodiment of the invention, a method of making a Cu—Ga alloy material having an average composition consisting of not less than 32% and not more than 53% by mass of gallium (Ga) as well as the balance consisting of copper (Cu) and an inevitable impurity comprises:

sintering in which a powder containing at least first Cu—Ga alloy phase and second Cu—Ga alloy phase are heated at a temperature in a range of 254° C. to 840° C. to melt the first Cu—Ga alloy phase and a part of the second Cu—Ga alloy phase and are pressed at a pressure of 50 MPa or more.

In the above embodiment (6) of the invention, the following modification and change can be made.

(i) The powder and powder consisting of phase of which an average composition contains 53% or more by mass of gallium are sintered in the sintering.

(ii) The Cu—Ga alloy material is subjected to heat treatment at a temperature in a range of 200° C. to 254° C. for 1 hour or more, after the sintering.

(7) According to another embodiment of the invention, a method of making a Cu—Ga alloy material having an average composition containing not less than 32% and not more than 53% by mass of gallium (Ga) comprises:

forming an ingot by melting and coagulating Cu—Ga alloy and an inevitable impurity in Ar atmosphere;

crushing the ingot to make powder;

sorting out powder having a grain diameter of 150 μm or less from the powder;

sintering the sorted powder through heating and pressing to make a Cu—Ga alloy material; and

carrying out heat treatment to the a Cu—Ga alloy material after the sintering.

(8) According to another embodiment of the invention, a method of making a Cu—In—Ga—Se alloy film used for a light-absorbing layer of a solar battery comprises:

forming an alloy film on an indium (In) layer by sputtering using a sputtering target made from the Cu—Ga alloy material according to the above embodiment (1); and

carrying out heat treatment to the alloy film in selenium (Se) atmosphere.

(9) According to another embodiment of the invention, a Cu—In—Ga—Se alloy film is made by the method according to the above embodiment (8).

Points of the Invention

According to an embodiment, since a content of segregation phase containing 80% or more by mass of gallium in the Cu—Ga alloy material is low, problems such as abnormal electrical discharge that occurs due to voids and oxides can be solved when sputtering is carried out using a sputtering target consisting of a Cu—Ga alloy material. Therefore, sputtering is carried out using the sputtering target consisting of a Cu—Ga alloy material of the embodiment, and a high-quality Cu—Ga alloy film can be thereby formed. For example, the high-quality Cu—Ga alloy film is formed on an indium (In) layer by sputtering using the sputtering target, and is subsequently subjected to heat treatment in selenium (Se) atmosphere, thereby making a high-quality Cu—In—Ga—Se alloy film. The Cu—In—Ga—Se alloy film can be used for a light-absorbing layer of solar batteries. Accordingly, solar battery having high conversion efficiency can be provided by making the solar batteries using the Cu—Ga alloy material of the embodiment.

### DETAILED DESCRIPTION OF THE PREFERRED EMBODIMENTS

Digest of an Embodiment

A Cu—Ga alloy material containing plural phases is provided in an embodiment of the invention. The Cu—Ga alloy material contains 32% to 53% (i.e. not less than 32% and not more than 53%) by mass of gallium (Ga) and the balance consisting of copper (Cu) and an inevitable impurity. Additionally, although the Cu—Ga alloy material includes segregation phase containing 80% or more by mass of gallium, the segregation phase and inevitable voids together accounts for 2% or less by volume of the whole Cu—Ga alloy material. For example, in the Cu—Ga alloy material, of which the average composition consists of 32% to 53% by mass of gallium (Ga) as well as the balance consisting of copper (Cu) and an inevitable impurity, a region containing less than 47% by mass of copper accounts for 2% or less by volume of the whole Cu—Ga alloy material.

### Embodiment

Brief Description of Cu—Ga Alloy Materials

For example, the Cu—Ga alloy material of the present embodiment is used as a sputtering target for forming Copper Indium Gallium DiSelenide (CIGS) solar batteries. As an example, the Cu—Ga alloy of the embodiment is used for a light-absorbing layer of solar batteries, etc., the light-absorbing layer consisting of a compound semiconductors film. Specifically, the Cu—Ga alloy of the embodiment can be used as a material of a light-absorbing layer of a solar battery that contains a glass substrate consisting of soda lime glass, an electrode layer formed on the glass substrate, the light-absorbing layer formed on the electrode layer, a buffer layer formed on the light-absorbing layer, and a transparent electrode layer formed on the buffer layer. For example, the electrode layer may be made from molybdenum (Mo) usable for a positive electrode. For example, the light-absorbing layer may be made of a Cu—In—Ga—Se quaterary alloy layer. The buffer layer may be made from ZnS, CdS, or the like. The transparent electrode layer functions as a negative electrode.

Hereinafter, the Cu—Ga alloy material of the embodiment is described in detail.

Cu—Ga Alloy Materials Containing No ε Phase

A Cu—Ga alloy material containing no ε phase of the embodiment has an average composition consisting of 32% to 53% by mass of gallium (Ga) as well as the balance consisting of copper (Cu) and an inevitable impurity, and a region thereof containing less than 47% by mass of copper accounts for 2% or less by volume of the whole Cu—Ga alloy material. Thus, a region except segregation phase accounts for 98% or more by volume of the whole Cu—Ga alloy material. Here, the region containing less than 47% by mass of copper includes inevitable voids.

Meanwhile, the average composition of the Cu—Ga alloy material may contain 32% to 45% by mass of gallium, and a region thereof containing inevitable voids and less than 35% by mass of copper accounts for 2% or less by volume of the whole Cu—Ga alloy material. It means that the Cu—Ga alloy material is composed of γ2 phase and γ3 phase.

Furthermore, the Cu—Ga alloy material may have an average composition that consists of 32% to 45% by mass of gallium as well as the balance consisting of copper, an inevitable impurity and inevitable voids. In the Cu—Ga alloy material, a region containing Cu—Ga alloy phase and inevitable voids accounts for 2% or less by volume of the whole Cu—Ga alloy material, the Cu—Ga alloy phase containing 65% or more by mass of gallium. Additionally, the Cu—Ga alloy phase contains at least one of γ1 phase, γ2 phase, and γ3 phase.

A method of making the Cu—Ga alloy material containing no ε phase, for example, is described as follows. First, powder containing at least one of phases selected from the group consisting of γ1 phase, γ2 phase, and γ3 phase is prepared. Here, the prepared powder includes inevitable voids. Then, the powder is pressed at a predetermined pressure while being heated at a predetermined temperature, and is thereby sintered. A part of the powder is liquefied and intrudes into voids in the powder, thereby decreasing volume of voids of the powder. As a result, the made Cu—Ga alloy material does not substantially include voids and contains no ε phase.

For example, a Cu—Ga alloy material having γ1 phase, single phase, may be made by preparing and sintering Cu—Ga alloy powder containing 32% by mass of gallium (i.e. powder contains γ1 phase of Cu—Ga alloy). A Cu—Ga alloy material containing γ1 phase and γ2 phase may be made by preparing and sintering mixed powder of Cu—Ga alloy powder containing γ1 phase and Cu—Ga alloy powder containing γ2 phase. A Cu—Ga alloy material having γ2 phase, single phase, may be made by preparing and sintering Cu—Ga alloy powder containing γ2 phase.

Additionally, a Cu—Ga alloy material containing γ2 phase and γ3 phase may be made by preparing and sintering mixed powder of Cu—Ga alloy powder containing γ2 phase and Cu—Ga alloy powder containing γ3 phase. In each of the Cu—Ga alloy materials, voids do not substantially exist after the sintering. In other words, voids account for 2% or less by volume of the whole made Cu—Ga alloy material.

Cu—Ga Alloy Materials that Contains ε Phase or does not Substantively Contain ε Phase

A Cu—Ga alloy material that contains ε phase or does not substantively contain ε phase of the embodiment has an average composition consisting of 32% to 53% by mass of gallium (Ga) as well as the balance consisting of copper (Cu), an inevitable impurity and inevitable voids. In the Cu—Ga alloy material, a region containing Cu—Ga alloy phase and inevitable voids accounts for 2% or less by volume of the whole Cu—Ga alloy material, the Cu—Ga alloy phase containing 80% or more by mass of gallium. Additionally, the Cu—Ga alloy phase contains a region consisting of γ1 phase, γ2 phase, and/or γ3 phase.

A method of making the Cu—Ga alloy material, which contains ε phase or does not substantively contain ε phase, for example, is described as follows. First, at least two Cu—Ga alloy powders containing γ3 phase and ε phase of four Cu—Ga alloy powders containing γ2 phase, γ3 phase, ε phase and segregation phase are prepared. Here, the prepared powder includes inevitable voids. Then, the powder is pressed at a predetermined pressure while being heated at a predetermined temperature, and is thereby sintered. A part of the powder is liquefied and intrudes into voids of the powder, thereby decreasing volume of voids in the powder. As a result, the made Cu—Ga alloy material does not substantially include voids, and contains ε phase or does not substantively contain ε phase.

For example, a Cu—Ga alloy material consisting of γ2 phase and γ3 phase may be made as follows. First, Cu—Ga alloy powder containing γ2 phase, Cu—Ga alloy powder containing γ3 phase, and Cu—Ga alloy powder containing ε phase is prepared and mixed. Here, Cu—Ga alloy powder containing segregation phase may exist in the mixed powder. Note that, each of the powders can be obtained by crushing an ingot consisting of Cu—Ga alloy containing the corresponding phase. Then, the mixed powder, in which inevitable voids is included, is pressed at a predetermined pressure while being heated at a predetermined temperature, and is thereby sintered. As a result, the Cu—Ga alloy material consisting of γ2 phase and γ3 phase can be obtained. Therefore, even if segregation phase or ε phase locally exist in the ingot, which is a raw material of the Cu—Ga alloy powder, the ε phase can substantively disappear from the made Cu—Ga alloy material.

Additionally, a Cu—Ga alloy material containing γ3 phase may be made by preparing and sintering mixed powder of Cu—Ga alloy powder containing γ3 phase and Cu—Ga alloy powder containing ε phase. As a result, the ε phase is reduced or substantively disappears in the made Cu—Ga alloy material containing γ3 phase.

Moreover, a Cu—Ga alloy material containing γ3 phase, ε phase and segregation phase may be made by preparing and sintering mixed powder of Cu—Ga alloy powder containing γ3 phase and Cu—Ga alloy powder containing ε phase. Here, Cu—Ga alloy powder containing segregation phase may exist in the mixed powder. As a result, rate of the ε phase in the made Cu—Ga alloy material, which contains γ3 phase, ε phase and segregation phase, is less than that of the mixed powder.

Brief Description of Method of Making the Cu—Ga Alloy Material

Powder consisting of Cu—Ga alloy containing at least one of the Cu—Ga alloy phases is pressed with heating and thereby sintered, and thus each of the Cu—Ga alloy materials described above is made. Specifically, the Cu—Ga alloy materials may be made as follows.

First, powder that contains Cu—Ga alloy grains having a grain diameter of 150 μm or less (e.g. 1 μm to 100 μm) is prepared. Here, an inevitable impurity and inevitable voids are included in the grains. Specifically, the grains are made as follows. First, an ingot that consists of Cu—Ga alloy containing predetermined phase is melted in an inert atmosphere (e.g. in Ar atmosphere), and is subsequently coagulated. Next, the coagulated ingot is crashed. Then, Cu—Ga alloy powder having a grain diameter of 150 μm or less is sorted out. Through such process, the Cu—Ga alloy powder can be obtained.

Next, for example, Cu—Ga alloy grains that contain γ phase having a grain diameter of 100 μm or less are mixed with Cu—Ga alloy grains that contain ε phase having a grain diameter of 40 μm or less and a melting point lower than that of γ phase, and mixed powder is thereby prepared. Here, the ε phase corresponds to first Cu—Ga alloy phase having a first melting point, and the γ phase corresponds to second Cu—Ga alloy phase having a second melting point. Additionally, this process is described as a mixing process. Note that, a part of Cu—Ga alloy powder has a grain diameter of 1 μm to 100 μm, and the part preferably accounts for 90% or more by volume of the whole of the intended Cu—Ga alloy material.

Next, a temperature of the mixed powder is maintained at a predetermined temperature in a range of 254° C. to 840° C. Accordingly, grains containing the ε phase, grains containing the γ phase, a part of grains containing the γ1 phase, a part of grains containing the γ2 phase, and a part of grains containing the γ3 phase are melted to make liquid binder. Here, this process is described as a melting process. Note that, in the embodiment, grains having a low melting point are melted more easily than grains having a high melting point because raw powder having a grain diameter of 100 μm or less is used. Thus, melt that is generated by melting of the grains having a low melting point intrudes into voids in the grains having a high melting point. Solidification of the melt, which has been generated from the grains having a low melting point, in the voids causes an effect in which segregation phase and the ε phase do not remain easily.

Next, the grains and the binder, which has been made by the melting of all or a part of each of the grains, are sintered while pressing at a pressure of 50 MPa or more. Here, this process is described as a sintering process. Furthermore, an alloy material obtained after the sintering is subjected to heat treatment at a temperature of from 200° C. to 254° C. for 1 hour or more. Here, this process is described as a heat treatment process. As a result, the Cu—Ga alloy material according to the embodiment is made.

The inside of the γ phase can be homogenized by maintaining of the temperature of the mixed powder at a temperature of 254° C. or more in the melting process. Note that, the γ phase is segregated in micro sizes in a process of melting, and Ga concentration of a crystal grain gets bigger at the outside of the crystal grain. Additionally, the ε phase having a melting point of 254° C. is melted and functions as binder (i.e. bonding agent) for grains containing the γ phase, which can densify the structure of the obtained alloy material by pressing at only pressure of from 50 MPa to 300 MPa. Here, since each of the γ phase and the γ phase is hard, a pressure of 600 MPa or more is required in order to make an alloy material having a closely packed structure by simply sintering powder containing the y phase and powder containing the γ phase. Therefore, according to the method of making the Cu—Ga alloy material of the embodiment, for example, high degree of freedom of equipments for pressing usable for upsizing of sputtering targets consisting of the Cu—Ga alloy material is allowed.

In addition, precipitation of segregation phase containing 80% or more by mass of gallium can be suppressed by carrying out heat treatment process. Furthermore, the precipitation of segregation phase can be suppressed further by making the grains containing the γ phase finer.

Effects of the Embodiment

Since a content of segregation phase containing 80% or more by mass of gallium in the Cu—Ga alloy material of the embodiment is low, problems such as abnormal electrical discharge that occurs due to voids and oxides can be solved when sputtering is carried out using a sputtering target consisting of a Cu—Ga alloy material made by sintering of powder.

Therefore, sputtering is carried out using the sputtering target consisting of a Cu—Ga alloy material of the embodiment, and a high-quality Cu—Ga alloy film can be thereby formed. For example, the high-quality Cu—Ga alloy film is formed on an indium (In) layer by sputtering using the sputtering target, and is subsequently subjected to heat treatment in selenium (Se) atmosphere, thereby making a high-quality Cu—In—Ga—Se alloy film. The Cu—In—Ga—Se alloy film can be used for a light-absorbing layer of solar batteries. Accordingly, solar battery having high conversion efficiency can be provided by making the solar batteries using the Cu—Ga alloy material of the embodiment.

### Examples

Hereinafter, the Cu—Ga alloy material of examples according to the invention is described.

A Cu—Ga alloy material according to example 1 has been made as follows. First, a Cu—Ga alloy ingot that contained 32% by mass of Ga and the balance consisting of Cu and an inevitable impurity was prepared. Next, the Cu—Ga alloy ingot was melted in Ar atmosphere by using a high frequency smelting furnace, and was subsequently coagulated. Then, the coagulated ingot was crashed, and Cu—Ga alloy grains having a grain diameter of 100 μm or less was sorted out to be used for Cu—Ga alloy powder as raw powder. After that, the Cu—Ga alloy powder, which had been obtained by the sorting, was sintered by using a pressing machine under the condition shown in “Example 1” in Table 1, thereby forming the Cu—Ga alloy material of example 1.

Additionally, a Cu—Ga alloy material according to example 2 was made as follows. First, a Cu—Ga alloy ingot that contained 53% by mass of Ga and the balance consisting of Cu and an inevitable impurity was prepared. Next, the Cu—Ga alloy ingot was melted in Ar atmosphere by using a high frequency smelting furnace, and was subsequently coagulated. Then, the coagulated ingot was crashed, and Cu—Ga alloy grains having a grain diameter of 100 μm or less was sorted out to be used for Cu—Ga alloy powder as raw powder. After that, the Cu—Ga alloy powder, which had been obtained by the sorting, was sintered by using a pressing machine under the condition shown in “Example 2” in Table 1, thereby forming the Cu—Ga alloy material of example 2.

Furthermore, the Cu—Ga alloy material of example 2 was subjected to heat treatment at 240° C. for 1 hour, the Cu—Ga alloy material according to example 3 was made thereby.

TABLE 1

| | Ga | Average | | | Area ratio |
|---|---|---|---|---|---|
| | concen- | crystal | | | of |
| | tration | grain | | Heat | segregation |
| | (% by | diameter | Sintering | treatment | phase and |
| | mass) | (μm) | condition | condition | voids (%) |
| Example 1 | 32 | 100 | 50 MPa, | No heat | 0.6 |
| | | | 840° C. | treatment | |
| Example 2 | 53 | | 50 MPa, | | 1.9 |
| Example 3 | | | 254° C. | 240° C. | 1.1 |
| Comparative | 60 | | | for 1 hour | 13.2 |
| example 1 | | | | | |
| Comparative | 53 | 200 | | | 8.2 |
| example 2 | | | | | |
| Comparative | | 100 | 25 MPa, | | 7.3 |
| example 3 | | | 254° C. | | |
| Comparative | | | 50 MPa, | | 5.1 |
| example 4 | | | 190° C. | | |

Each of the Cu—Ga alloy materials of examples 1 to 3 made by the above-described processes was cut at the center thereof, then an area ratio that is ratio of area of segregation phase and voids to total area of the cross section was calculated. Note that, the area ratio of the segregation phase and voids was calculated by separating the segregation phase and voids from the mother phase with respect to brightness in the crystal structure on the cross section by using the image analyzing software, Image-Pro Plus J from Nippon Roper K.K. As a result, 0.6% area ratio and 1.9% area ratio were respectively obtained in examples 1 and 2. Additionally, 1.1% area ratio was obtained in Example 3. That means the Cu—Ga alloy material having a closely packed structure was obtained in each of the examples 1 to 3.

### Comparative Examples

Cu—Ga alloy materials according to comparative examples 1 to 4 having the corresponding composition and crystal grain diameter shown in Table 1 were made under the corresponding sintering condition and heat treatment condition in Table 1. Then, an area ratio that is ratio of area of segregation phase containing 80% or more by mass of gallium and voids to total area of a cross section in each of the made Cu—Ga alloy materials of the comparative examples 1 to 4 was calculated, as was the case with the examples.

As a result, it was shown that the area ratio, which is ratio of the area of the segregation phase and voids to the total area of the cross section, is as high as 5% or more in each of the Cu—Ga alloy materials of the comparative examples 1 to 4.

In the comparative example 1, Ga concentration was out of the range stipulated in the embodiment in the invention. Since the Ga concentration was higher than the stipulated range in the comparative example 1, segregation phase occurred easily and the area ratio was thereby 13.2% or more.

In the comparative example 2, crystal grain diameter was out of the range stipulated in the embodiment in the invention. Since the crystal grain diameter was large in the comparative example 2, segregation phase and voids remained easily in the made Cu—Ga alloy material and the area ratio was thereby 8.2% or more.

In the comparative example 3, pressure in sintering was out of the range stipulated in the embodiment in the invention. Since the pressure in sintering was low in the comparative example 3, voids remained easily in the made Cu—Ga alloy material and the area ratio was thereby 7.3% or more.

Furthermore, in the comparative example 4, temperature in sintering was out of the range stipulated in the embodiment in the invention. Since the temperature in sintering was low in the comparative example 4, voids remained easily in the made Cu—Ga alloy material and the area ratio was thereby 5.1% or more.

Although the embodiment and Examples of the invention have been described above, the invention according to claims is not to be limited to the above-mentioned embodiment and Examples. Further, please note that not all combinations of the features described in the embodiment and Examples are not necessary to solve the problem of the invention.

What is claimed is:

1. A Cu—Ga alloy material, having:
an average composition consisting of not less than 32% and not more than 53% by mass of gallium (Ga) as well as the balance consisting of copper (Cu) and an inevitable impurity,
wherein a region containing less than 47% by mass of copper accounts for 2% or less by volume of the whole Cu—Ga alloy material.

2. The Cu—Ga alloy material according to claim 1, wherein the average composition contains not less than 32% and not more than 45% by mass of gallium; and
a region containing less than 35% by mass of copper accounts for 2% or less by volume of the whole Cu—Ga alloy material.

3. A Cu—Ga alloy material, having:
an average composition consisting of not less than 32% and not more than 53% by mass of gallium (Ga) as well as the balance consisting of copper (Cu), an inevitable impurity and inevitable voids,
wherein a region consisting of a Cu—Ga alloy phase and the inevitable voids accounts for 2% or less by volume of the whole Cu—Ga alloy material, the Cu—Ga alloy phase contains 80% or more by mass of gallium.

4. A Cu—Ga alloy material, having:
an average composition consisting of not less than 32% and not more than 45% by mass of gallium (Ga) as well as the balance consisting of copper (Cu), an inevitable impurity and inevitable voids,
wherein a region consisting of a Cu—Ga alloy phase and the inevitable voids accounts for 2% or less by volume of the whole Cu—Ga alloy material, the Cu—Ga alloy phase contains 65% or more by mass of gallium; and
the Cu—Ga alloy phase contains at least one of γ1 phase, γ2 phase, and ₇3 phase.

5. A sputtering target made from the Cu—Ga alloy material according to claim 1.

6. A method of making a Cu—Ga alloy material containing a plurality of Cu—Ga alloy phases, comprising:
sintering by pressing and heating Cu—Ga alloy powder containing at least one of the Cu—Ga alloy phases.

7. The method according to claim 6, wherein the Cu—Ga alloy powder has a grain diameter of 150 μm or less.

8. The method according to claim 7, wherein a part of Cu—Ga alloy powder has a grain diameter of not less than 1 μm and not more than 100 μm; and
the part accounts for 90% or more by volume of the whole of the whole Cu—Ga alloy material.

9. The method according to claim 6, wherein the Cu—Ga alloy material consists of not less than 32% and not more than 53% by mass of gallium (Ga) as well as the balance consisting of copper (Cu) and an inevitable impurity; and
in the sintering, powder consisting of phase of which an average composition contains 53% or more by mass of gallium and powder comprising at least first Cu—Ga alloy phase and second Cu—Ga alloy phase are heated at a temperature in a range of 254° C. to 840° C. to melt the first Cu—Ga alloy phase and a part of the second Cu—Ga alloy phase and are pressed at a pressure of 50 MPa or more, the first Cu—Ga alloy phase having a first melting point, and the second Cu—Ga alloy phase having a second melting point higher than the first melting point.

10. A method of making a Cu—Ga alloy material having an average composition consisting of not less than 32% and not more than 53% by mass of gallium (Ga) as well as the balance consisting of copper (Cu) and an inevitable impurity, comprising:
sintering in which a powder containing at least first Cu—Ga alloy phase and second Cu—Ga alloy phase are heated at a temperature in a range of 254° C. to 840° C. to melt the first Cu—Ga alloy phase and a part of the second Cu—Ga alloy phase and are pressed at a pressure of 50 MPa or more.

11. The method according to claim 10, wherein the powder and powder consisting of phase of which an average composition contains 53% or more by mass of gallium are sintered in the sintering.

12. The method according to claim 11, wherein the Cu—Ga alloy material is subjected to heat treatment at a temperature in a range of 200° C. to 254° C. for 1 hour or more, after the sintering.

13. A method of making a Cu—Ga alloy material having an average composition containing not less than 32% and not more than 53% by mass of gallium (Ga), comprising:
forming an ingot by melting and coagulating Cu—Ga alloy and an inevitable impurity in Ar atmosphere;
crushing the ingot to make powder;
sorting out powder having a grain diameter of 150 μm or less from the powder;
sintering the sorted powder through heating and pressing to make a Cu—Ga alloy material; and
carrying out heat treatment to the Cu—Ga alloy material after the sintering.

14. A method of making a Cu—In—Ga—Se alloy film used for a light-absorbing layer of a solar battery, comprising:
forming an alloy film on an indium (In) layer by sputtering using a sputtering target made from the Cu—Ga alloy material according to claim 1; and
carrying out heat treatment to the alloy film in selenium (Se) atmosphere.

15. A Cu—In—Ga—Se alloy film made by the method according to claim 14.
